(19) United States
(12) Patent Application Publication
(10) Pub. No.: US 2025/0091095 A1
(43) Pub. Date: Mar. 20, 2025

(54) SUBSTRATE CLEANING APPARATUS AND SUBSTRATE CLEANING METHOD

(71) Applicant: SHIBAURA MECHATRONICS CORPORATION, Kanagawa (JP)

(72) Inventors: Koichi HIGUCHI, Kanagawa (JP); Konosuke HAYASHI, Kanagawa (JP)

(21) Appl. No.: 18/891,253

(22) Filed: Sep. 20, 2024

(30) Foreign Application Priority Data
Sep. 20, 2023 (JP) 2023-152917

(51) Int. Cl. B08B 1/12; B08B 3/02

(52) U.S. Cl. CPC B08B 1/12; B08B 3/022

(57) ABSTRACT

According to one embodiment, a substrate cleaning apparatus includes: a cleaning liquid supply unit for supplying a cleaning liquid to a rotating substrate, a first cleaning head for cleaning at least one surface of the rotating substrate by bringing a brush into contact with the one surface of the substrate, a second cleaning head for cleaning the one surface of the substrate by bringing a brush into contact with the one surface of the substrate, a turning arm for turning the first cleaning head and the second cleaning head, and a controller. The controller controls the turning arm such that, during cleaning in which a brush of one of the first cleaning head and the second cleaning head is brought into contact with a surface of the substrate to perform cleaning, the brush of the other is positioned at a position outside the substrate.

### CROSS-REFERENCE TO RELATED APPLICATION

The present application claims priority to and incorporates by reference the entire contents of Japanese Patent Application No. 2023-152917 filed in Japan on Sep. 20, 2023.

### TECHNICAL FIELD

Embodiments described herein relate to a substrate cleaning apparatus and a substrate cleaning method.

### BACKGROUND

A substrate processing apparatus is an apparatus that processes a surface to be processed of a substrate (for example, a wafer or a liquid crystal substrate) with a chemical liquid in a manufacturing process of a semiconductor, a liquid crystal panel or the like, washes the substrate with a rinse liquid after the chemical liquid process, and dries the substrate after rinsing. In the substrate processing apparatus, a single-wafer type in which substrates are processed one by one is used in terms of uniformity and reproducibility.

In a single-wafer type substrate processing apparatus, a substrate is placed on a rotary table, a processing liquid such as a chemical liquid is supplied to the substrate on the rotating rotary table, and the substrate is processed by the processing liquid. After the substrate processing process by the processing liquid, substrate cleaning is performed in order to maintain high cleanliness of the substrate. In addition, when a substrate processing process is performed a plurality of times by a plurality of types of processing liquids, the substrate cleaning may be performed for each process in order to maintain high cleanliness of the substrate.

As a substrate cleaning method, scrub cleaning by a brush is used. In this scrub cleaning, a brush is stopped or rotated in a state where a substrate is rotated, and the brush is horizontally moved while being brought into contact with the surface of the substrate to remove impurities (metal, organic substances, particles, and the like) on the substrate.

In recent years, due to quality requirements associated with miniaturization of semiconductor devices, substrates are required to be processed with higher cleanliness in scrub cleaning. For example, when the cleanliness of a brush is low, impurities adhered to the brush may contaminate a substrate, and substrate quality may be degraded.

### BRIEF DESCRIPTION OF THE DRAWINGS

FIG. 1 is a plan view illustrating an example of a configuration of a substrate processing apparatus according to an embodiment;

FIG. 2 is a side view illustrating an example of a schematic configuration of the substrate processing apparatus according to the embodiment;

FIG. 3 is a diagram illustrating an example of a schematic configuration of a first self-cleaning stage according to the embodiment;

FIG. 4 is a diagram for explaining a case where a first cleaning head and second cleaning head according to the embodiment swing;

FIG. 5 is a flowchart illustrating a flow of an example of a process performed by the substrate processing apparatus according to the embodiment;

FIG. 6 is a diagram illustrating an example of the operation of the substrate processing apparatus in step S107 according to the embodiment;

FIG. 7 is a diagram illustrating an example of a state after the operation of the substrate processing apparatus in step S107 according to the embodiment; and

FIG. 8 is a diagram illustrating an example of the operation of the substrate processing apparatus in step S114 according to the embodiment.

### DETAILED DESCRIPTION OF THE PREFERRED EMBODIMENTS

### Embodiments

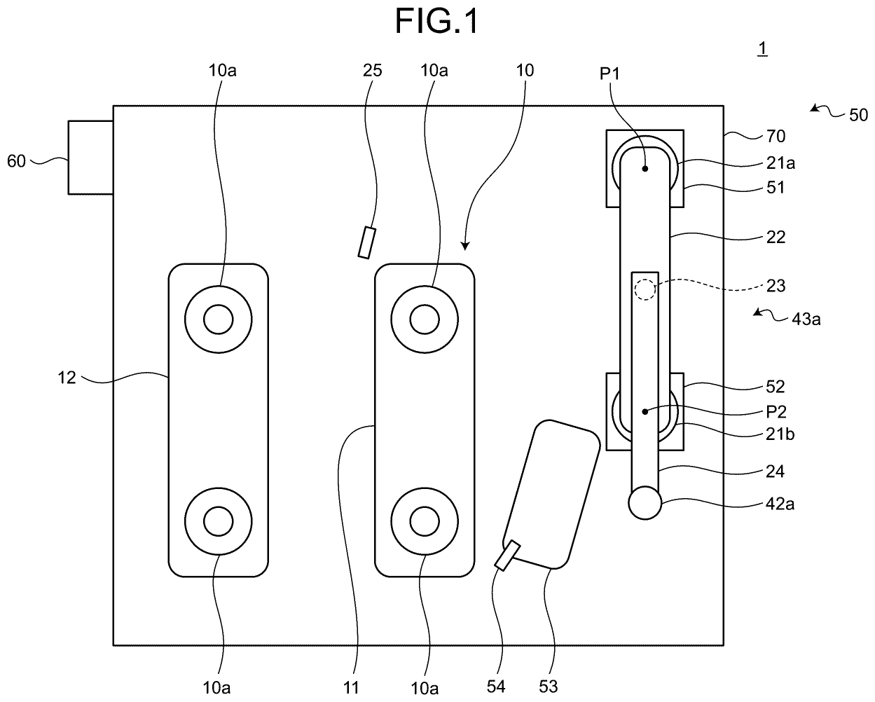

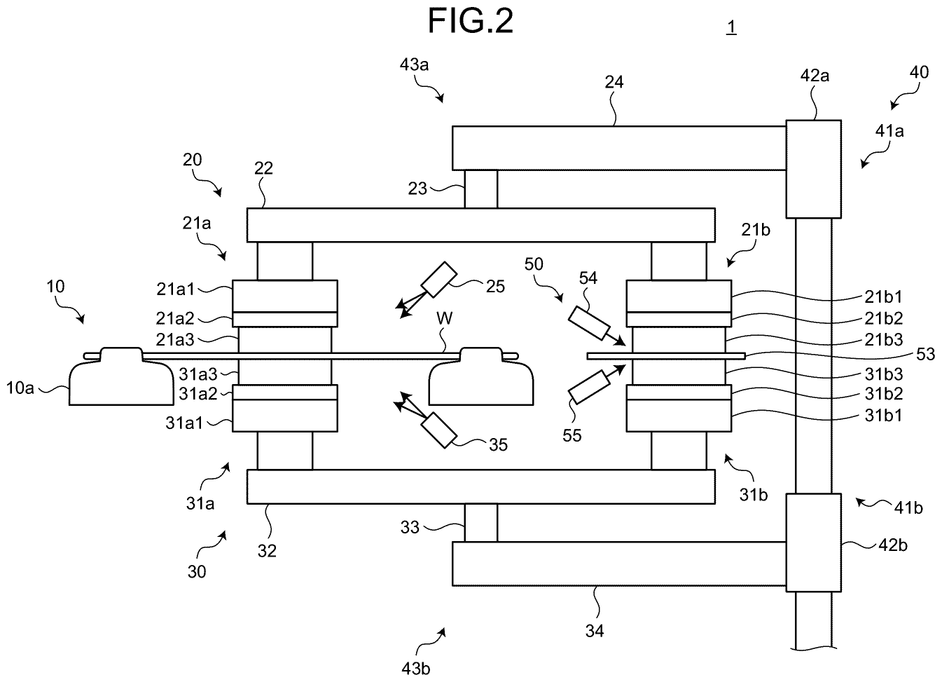

Embodiments will be described below with reference to the drawings. FIG. 1 is a plan view illustrating an example of a schematic configuration of a substrate processing apparatus 1 according to an embodiment. FIG. 2 is a side view illustrating an example of a schematic configuration of the substrate processing apparatus 1 according to the embodiment. The substrate processing apparatus 1 according to the present embodiment performs a substrate cleaning process of cleaning a substrate W with a cleaning liquid and a brush while rotating the substrate W in a held state. The substrate W is typically a semiconductor wafer, but may be a liquid crystal substrate for a display device, or the like. Note that FIG. 1 illustrates the substrate processing apparatus 1 before the substrate W is carried in, and FIG. 2 illustrates the substrate processing apparatus 1 in which the substrate W is carried in and a substrate cleaning process is being performed.

For example, the substrate processing apparatus 1 according to the present embodiment is a single-wafer type substrate processing apparatus. The substrate processing apparatus 1 performs a substrate cleaning process on the carried-in substrate W, and performs a brush cleaning process (also referred to as a self-cleaning process) of cleaning a brush during the substrate cleaning process and after the substrate cleaning process. Further, the substrate processing apparatus 1 performs a rinse process of washing the substrate W after the substrate cleaning process with a rinse liquid. Then, after the rinse process, the substrate processing apparatus 1 carries out the substrate W subjected to the rinse process. Then, when the next substrate W is carried in, the substrate processing apparatus 1 performs the various processes described above. In other words, every time the substrate W is carried in, the substrate processing apparatus 1 performs the various processes described above on the carried-in substrate W. As described above, the substrate processing apparatus 1 is an example of a substrate cleaning apparatus that performs substrate cleaning. The configuration of the substrate processing apparatus 1 and the substrate cleaning process and the brush cleaning process performed by the substrate processing apparatus 1 will be described below in detail.

As illustrated in FIGS. 1 and 2, the substrate processing apparatus 1 has a rotation mechanism 10, a first cleaning mechanism 20, a second cleaning mechanism 30, a drive mechanism 40, a brush cleaning unit 50, a control device 60, and a processing chamber 70. Among these described above, the rotation mechanism 10, the first cleaning mechanism 20, the second cleaning mechanism 30, the drive mechanism 40, and the brush cleaning unit 50 other than the control device 60 are provided in the processing chamber 70.

The rotation mechanism 10 rotates the substrate W in a held state. The rotation mechanism 10 has a first holding unit 11, a second holding unit 12, a first rotation drive unit (not illustrated), and a second rotation drive unit (not illustrated). The first holding unit 11 and the second holding unit 12 are disposed at positions facing each other with the substrate W interposed therebetween. Note that, in FIG. 2, the first holding unit 11 and the second holding unit 12 are not illustrated.

Each of the first holding unit 11 and the second holding unit 12 has a pair of rollers 10a. The roller 10a is provided to be rotatable about an axis orthogonal to the surface direction of the substrate W. Each roller 10a in the first holding unit 11 and the second holding unit 12 has a large-diameter portion and a small-diameter portion provided on the upper surface of the large-diameter portion, and the side surfaces of the large-diameter portion and the small-diameter portion are tapered so that the diameter of the boundary where the side surfaces are in contact with each other decreases. A boundary portion between the large-diameter portion and the small-diameter portion of each roller 10a comes into contact with the substrate W, thereby holding the peripheral portion of the substrate W.

The first rotation drive unit supports the first holding unit 11, and the second rotation drive unit supports the second holding unit 12. Each of the first rotation drive unit and the second rotation drive unit rotates the roller 10a about the axis (drive shaft) of the roller 10a and moves the roller 10a in a direction in which the roller comes in contact with or separates from the substrate W. A turning mechanism (not illustrated) for driving the roller 10a is housed inside the first rotation drive unit and the second rotation drive unit.

The turning mechanism is, for example, a belt drive mechanism. In other words, a timing belt is stretched between a pulley provide on a drive shaft of a motor serving as a drive source and a pulley provided on a drive shaft of one of the rollers 10a and between pulleys provided on the drive shafts of the pair of rollers 10a, whereby the pair of rollers 10a is rotatably provided by a drive source. Note that the turning mechanism is not limited thereto, and may be configured to rotate each roller 10a by the motor provided in each roller 10a, for example.

Each of the first rotation drive unit and the second rotation drive unit is provided with a drive mechanism (not illustrated) for moving each of the first holding unit 11 and the second holding unit 12 in a direction in which the roller 10a comes into contact with or separates from the substrate W. The drive mechanism has a rotary cylinder for moving a drive shaft provided at the lower end of the first rotation drive unit and a drive shaft provided at the lower end of the second rotation drive unit in directions opposite to each other along a direction parallel to the surface of the substrate W.

The drive mechanism moves the first holding unit 11 and the second holding unit 12 in directions away from each other, so that the rollers 10a are separated from the substrate W to release the substrate W. The drive mechanism moves the first holding unit 11 and the second holding unit 12 in directions approaching each other, so that the rollers 10a come into contact with the substrate W to hold the substrate W. In a state where the substrate W is held by the plurality of rollers 10a, the substrate W is rotated by the rotation of each roller 10a.

The first cleaning mechanism 20 is a mechanism for cleaning a first surface (an upper surface in the present embodiment) of the substrate W held by the plurality of rollers 10a. The first cleaning mechanism 20 has cleaning heads 21a and 21b, a first turning arm 22, a first joint mechanism 23, a first swing arm 24, and a cleaning liquid supply unit 25.

The cleaning heads 21a and 21b clean the first surface of the substrate W by bringing rotating brushes 21a3 and 21b3 into contact with the first surface of the rotating substrate W. The term “contact” as used herein includes a case where the brushes 21a3 and 21b3 are in direct contact with the substrate W and a case where the brushes are in contact with the substrate W via a cleaning liquid.

The cleaning head 21a has a support 21al, a holder 21a2, and the brush 21a3. The support 21al is a cylindrical vessel and houses a motor therein. The motor is a drive source for rotating the brush 21a3, and is, for example, a hollow motor having a cylindrical drive shaft.

The holder 21a2 is a disc-shaped member attached to the drive shaft of the motor housed in the support 21al. The holder 21a2 is rotatably provided independently of the support 21al. The brush 21a3 is fixed to the holder 21a2.

The brush 21a3 is a columnar member formed of a flexible and elastic material. For example, a brush formed of sponge-like resins such as PVA (nylon-based resin) and PTFE (fluorine-based resin) is used as the brush 21a3. Note that a similar resin-made bristle brush may be used as the brush 21a3. In other words, the brush 21a3 of the present embodiment also includes a brush of a sponge-like lump and a brush in which a large number of bristles are densely packed. Further, the number of brushes 21a3 provided on the holder 21a2 may be one or may be more than one. In the present embodiment, one brush 21a3 is provided for the holder 21a2.

The cleaning head 21b has a support 21b1, a holder 21b2, and the brush 21b3. Since the configuration of the cleaning head 21b is the same as that of the cleaning head 21a, the description thereof will be omitted.

The first turning arm 22 turns the cleaning heads 21a and 21b in a direction parallel to the first surface of the substrate W. The first turning arm 22 is a linearly extending member, and the cleaning head 21a is attached to a portion on one end side of the first turning arm 22 and the cleaning head 21b is attached to a portion on the other end side of the first turning arm 22. The length from one end to the other end of the first turning arm 22 is, for example, longer than the radius of the substrate W.

The first joint mechanism 23 connects the first turning arm 22 and the first swing arm 24. For example, one end (lower end) of the first joint mechanism 23 in the vertical direction is connected to a central portion in the direction in which the first turning arm 22 extends. One end of the first joint mechanism 23 is fixed to the first turning arm 22. On the other hand, the other end of the first joint mechanism 23 is supported by the first swing arm 24, but is not fixed to the first swing arm 24. As described above, the first joint mechanism 23 is turnably supported by the first swing arm 24.

The first swing arm 24 swings, via the first joint mechanism 23 and the first turning arm 22, the cleaning heads 21a and 21b by reciprocating the cleaning heads 21a and 21b attached to the first turning arm 22 in a direction parallel to the first surface of the substrate W along an arc trajectory. The first swing arm 24 is a linearly extending member and is supported by a swing mechanism 42a so as to be parallel to the first surface of the substrate W. A portion on one end side of the first swing arm 24 turnably supports the first joint mechanism 23.

The cleaning liquid supply unit 25 supplies a cleaning liquid to the first surface of the substrate W. The cleaning liquid is ozone water, pure water, or SC-1 (a mixed liquid of ammonia water and hydrogen peroxide water). For example, when the substrate W is cleaned with pure water, brushes formed of, for example, PVA are used as the brushes 21a3 and 21b3. Further, when ozone water or SC-1 is used as the cleaning liquid, brushes formed of, for example, PTFE are used as the brushes 21a3 and 21b3. Since PTFE has chemical liquid resistance, PTFE can be used in combination with a cleaning liquid such as ozone water or SC-1.

The cleaning liquid supply unit 25 is connected to a cleaning liquid supply device which is not illustrated. The supply device has a liquid feeding device, a valve, and the like connected to a pure water manufacturing device (pure water storage tank), an ozone water manufacturing device (ozone water storage tank), and an SC-1 supply device, and can switch and supply any one of pure water, ozone water, and SC-1 to the cleaning liquid supply unit 25.

The second cleaning mechanism 30 is a mechanism for cleaning a second surface (a lower surface in the present embodiment) of the substrate W held by the plurality of rollers 10a. The second cleaning mechanism 30 has cleaning heads 31a and 31b, a second turning arm 32, a second joint mechanism 33, a second swing arm 34, and a cleaning liquid supply unit 35. The second cleaning mechanism 30 has the same configuration as the first cleaning mechanism 20, and is provided upside down with respect to the first cleaning mechanism 20.

The cleaning heads 31a and 31b clean the second surface of the substrate W by bringing rotating brushes 31a3 and 31b3 into contact with the second surface of the rotating substrate W. The term “contact” as used herein includes a case where the brushes 31a3 and 31b3 are in direct contact with the substrate W and a case where the brushes are in contact with the substrate W via a cleaning liquid.

The cleaning head 31a has a support 31al, a holder 31a2, and a brush 31a3. Further, the cleaning head 31b has a support 31b1, a holder 31b2, and a brush 31b3. Since the configurations of the cleaning heads 31a and 31b are the same as that of the cleaning head 21a, the description thereof will be omitted.

The second turning arm 32 turns the cleaning heads 31a and 31b in a direction parallel to the second surface of the substrate W. The second joint mechanism 33 connects the second turning arm 32 and the second swing arm 34. The second swing arm 34 swings, via the second joint mechanism 33 and the second turning arm 32, the cleaning heads 31a and 31b by reciprocating the cleaning heads 31a and 31b attached to the second turning arm 32 in a direction parallel to the second surface of the substrate W along an arc trajectory. The cleaning liquid supply unit 35 supplies a cleaning liquid to the second surface of the substrate W. The configurations of the second turning arm 32, the second joint mechanism 33, the second swing arm 34, and the cleaning liquid supply unit 35 are the same as the configurations of the first turning arm 22, the first joint mechanism 23, the first swing arm 24, and the cleaning liquid supply unit 25, respectively, and thus the description thereof will be omitted.

The cleaning heads 21a and 21b, the first turning arm 22, the first joint mechanism 23, the first swing arm 24, and the cleaning liquid supply unit 25 as described above are provided on the first surface side of the substrate W, and the cleaning heads 31a and 31b, the second turning arm 32, the second joint mechanism 33, the second swing arm 34, and the cleaning liquid supply unit 35 are provided on the second surface side of the substrate W. Thus, the first surface and the second surface of the substrate W can be cleaned.

Note that, in the present embodiment, the cleaning head 21a and the cleaning head 31a are controlled such that the positions of the cleaning heads in the horizontal direction are the same. Similarly, the cleaning head 21b and the cleaning head 31b are also controlled such that the positions of the cleaning heads in the horizontal direction are the same. In the following description, the cleaning head 21a and the cleaning head 31a may be collectively referred to as a first cleaning head, and the cleaning head 21b and the cleaning head 31b may be collectively referred to as a second cleaning head.

The drive mechanism 40 includes lift mechanisms 41a and 41b, swing mechanisms 42a and 42b, and turning mechanisms 43a and 43b.

The lift mechanism 41a moves the first swing arm 24 in the vertical direction. Further, the lift mechanism 41b moves the second swing arm 34 in the vertical direction. In other words, the lift mechanisms 41a and 41b lift and lower the first swing arm 24 and the second swing arm 34. As described above, the lift mechanisms 41a and 41b move the cleaning head 21a and the cleaning head 31a in the vertical direction so as to come into contact with or separate from each other, and move the cleaning head 21b and the cleaning head 31b in the vertical direction so as to come into contact with or separate from each other. As the lift mechanisms 41a and 41b, a ball screw mechanism, a cylinder, or the like for lifting and lowering the support shafts of the first swing arm 24 and the second swing arm 34 may be applied.

The swing mechanism 42a causes the first swing arm 24 to reciprocate in a direction parallel to the first surface of the substrate W along an arc trajectory about an end portion of the first swing arm 24 opposite to the end portion provided with the first joint mechanism 23. The swing mechanism 42a has a support shaft (not illustrated) extending in a direction orthogonal to the first surface direction of the substrate W, and a motor (not illustrated) as a drive source for turning the support shaft. The first swing arm 24 is attached to the support shaft. When the support shaft is turned by the motor, the cleaning heads 21a and 21b attached to the first turning arm 22 via the first swing arm 24, the first joint mechanism 23, and the first turning arm 22 are reciprocated in a direction parallel to the first surface of the substrate W along the arc trajectory described above. The swing mechanism 42b causes the second swing arm 34 to reciprocate in a direction parallel to the second surface of the substrate W along an arc trajectory about an end portion of the second swing arm 34 opposite to the end portion provided with the second joint mechanism 33. Since the configuration of the swing mechanism 42b is the same as that of the swing mechanism 42a, the description thereof will be omitted.

When the first cleaning head and the second cleaning head do not clean the substrate W, the first cleaning head is controlled to be positioned at a predetermined standby position P1 or a predetermined standby position P2 outside a region where the substrate W is held, and the second cleaning head is controlled to be positioned at the standby position P2 or the standby position P1. The example of FIG. 1 illustrates a case where the first cleaning head (for example, the position of the center of gravity of the first cleaning head) is positioned at the standby position P1 and the second cleaning head (for example, the position of the center of gravity of the second cleaning head) is positioned at the standby position P2. Note that the standby position P1 is a position at which the brush of the cleaning head can be cleaned by a first self-cleaning stage 51 to be described later when the cleaning head is positioned at the standby position P1. Similarly, the standby position P2 is a position at which the brush of the cleaning head can be cleaned by a second self-cleaning stage 52 to be described later when the cleaning head is positioned at the standby position P2.

The turning mechanism 43a turns the cleaning heads 21a and 21b in a direction parallel to the first surface of the substrate W by turning the first turning arm 22 about the first joint mechanism 23. The turning mechanism 43a is, for example, a belt drive mechanism. In other words, a timing belt is stretched between a pulley provided on a drive shaft of a motor serving as a drive source and a pulley provided on a drive shaft (a rotation shaft extending in the vertical direction) of the first joint mechanism 23, whereby the first joint mechanism 23 is turnably provided by a drive source. Note that the turning mechanism 43a is not limited thereto, and for example, may be configured to turn the first joint mechanism 23 by a motor provided in the first joint mechanism 23.

The turning mechanism 43b turns the cleaning heads 31a and 31b in a direction parallel to the second surface of the substrate W by turning the second turning arm 32 about the second joint mechanism 33. Since the configuration of the turning mechanism 43b is the same as the configuration of the turning mechanism 43a, the description thereof will be omitted.

The brush cleaning unit 50 cleans the brushes 21a3, 21b3, 31a3, and 31b3. The brush cleaning unit 50 includes a first self-cleaning stage 51, a second self-cleaning stage 52, a self-cleaning substrate 53, and a cleaning liquid supply units (nozzles) 54 and 55.

The first self-cleaning stage 51 cleans the brush of the cleaning head positioned at the standby position P1. For example, when the first cleaning head is positioned at the standby position P1, the first self-cleaning stage 51 cleans the brushes 21a3 and 31a3. When the second cleaning head is positioned at the standby position P1, the first self-cleaning stage 51 cleans the brushes 21b3 and 31b3. Note that, in FIG. 2, the first self-cleaning stage 51 and the second self-cleaning stage 52 are not illustrated.

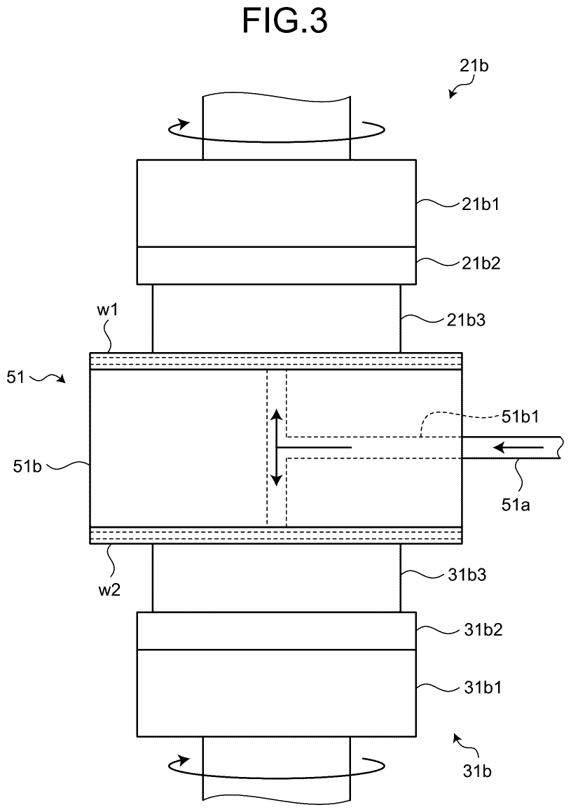

FIG. 3 is a diagram illustrating an example of a schematic configuration of the first self-cleaning stage 51 according to the embodiment. Note that the example of FIG. 3 illustrates a case where the first self-cleaning stage 51 cleans the brushes 21b3 and 31b3. As illustrated in FIG. 3, the first self-cleaning stage 51 includes a supply pipe 51a and a cleaning member 51b. The supply pipe 51a is connected to a tank in which the cleaning liquid is stored. The first self-cleaning stage 51 supplies the cleaning liquid in the tank to the upper surface (an example of the outer surface) and the lower surface of the cleaning member 51b to form a liquid film w1 of the cleaning liquid on the upper surface and form a liquid film w2 of the cleaning liquid on the lower surface. Then, the liquid film w1 of the cleaning liquid and the rotating brush (the brush 21a3 or the brush 21b3) are brought into contact with each other, and the liquid film w2 of the cleaning liquid and the rotating brush (the brush 31a3 or the brush 31b3) are brought into contact with each other, thereby cleaning the two brushes without bringing the cleaning member 51b into contact with the two rotating brushes. As described above, the first self-cleaning stage 51 cleans the brush in a non-contact manner. Note that the liquid films w1 and w2 have a thickness of about several millimeters.

The cleaning member 51b holds the liquid film w1 of the cleaning liquid on the upper surface, holds the liquid film w2 of the cleaning liquid on the lower surface, and cleans the brush by the held liquid films w1 and w2 of the cleaning liquid. The brush is constantly rotated during the substrate cleaning and the brush cleaning. Note that the separation distance between the upper surface of the cleaning member 51b and the lower surface of the brush of the first cleaning mechanism 20 positioned at the standby position P1 is set in advance. Further, the separation distance between the lower surface of the cleaning member 51b and the upper surface of the brush of the second cleaning mechanism 30 positioned at the standby position P1 is set in advance. A through-hole 51bi is formed inside the cleaning member 51b. The through-hole 51bi functions as a flow path through which a cleaning liquid for brush cleaning flows. The through-hole 51bi is opened on the side surface of the cleaning member 51b, is branched so as to extend in the vertical direction at the center of the cleaning member 51b, and is opened at the center of the upper surface of the cleaning member 51b and the center of the lower surface of the cleaning member 51b. The supply pipe 51a is connected to the opening on the side surface of the cleaning member 51b. The cleaning liquid flowing into the through-hole 51bi of the cleaning member 51b via the supply pipe 51a is discharged from the opening on the upper surface of the cleaning member 51b. Further, the cleaning liquid flowing into the through-hole 51bi of the cleaning member 51b via the supply pipe 51a is discharged from the opening on the lower surface of the cleaning member 51b. As the cleaning member 51b, an insulating resin member (for example, polyvinyl chloride) is used, for example.

Here, the cleaning liquid supplied to the upper surface and the lower surface of the cleaning member 51b flows down from the outer periphery of the cleaning member 51b and is discharged from a liquid discharge pipe (not illustrated) provided at the bottom of the processing chamber 70. Further, the cleaning liquid is constantly supplied to the upper surface and the lower surface of the cleaning member 51b during the substrate processing. Therefore, during the substrate processing, the cleaning liquid constantly flows on the upper surface and the lower surface of the cleaning member 51b. Since the processing liquid constantly flows, the upper surface and the lower surface of the cleaning member 51b can be maintained in a clean state. This is because, even if particles fall from the brush onto the cleaning member 51b, the particles are quickly discharged from the cleaning member 51b together with the cleaning liquid by the flow of the cleaning liquid. Further, since the upper surface and the lower surface (the surface facing the brush) of the cleaning member 51b are not dried by the flow of the cleaning liquid, it is possible to suppress the particles from being fixed due to the drying of the cleaning liquid.

The second self-cleaning stage 52 cleans the brush of the cleaning head positioned at the standby position P2. For example, when the first cleaning head is positioned at the standby position P2, the second self-cleaning stage 52 cleans the brushes 21a3 and 31a3. When the second cleaning head is positioned at the standby position P2, the second self-cleaning stage 52 cleans the brushes 21b3 and 31b3. Since the configuration of the second self-cleaning stage 52 is the same as that of the first self-cleaning stage 51, the description thereof will be omitted.

The first self-cleaning stage 51 and the second self-cleaning stage 52 are provided outside a region where the substrate W is held by the plurality of rollers 10a, with a distance corresponding to the distance between the two brushes 21a3 and 21b3 provided on the first turning arm 22 (the distance between the two brushes 31a3 and 31b3 provided on the second turning arm 32) in plan view.

The self-cleaning substrate 53 is provided outside a region where the substrate W is held by the plurality of rollers 10a and in a region (second position) where, when a brush of one cleaning head of the first cleaning head and the second cleaning head is positioned at a position (first position) where the brush cleans the substrate W while being in contact with the substrate, a brush of the other cleaning head is positioned. For example, FIG. 2 illustrates a case where the brush of the first cleaning head is positioned at the first position and the brush of the second cleaning head is positioned at the second position.

The cleaning liquid supply unit 54 supplies a cleaning liquid to the first surface (upper surface in the present embodiment) of the self-cleaning substrate 53, and the cleaning liquid supply unit 55 supplies a cleaning liquid to the second surface (lower surface in the present embodiment) of the self-cleaning substrate 53. The cleaning liquid supplied to the self-cleaning substrate 53 by the cleaning liquid supply units 54 and 55 is, for example, pure water. Since the configurations of the cleaning liquid supply units 54 and 55 are the same as that of the cleaning liquid supply unit 25, the description thereof will be omitted.

The brush (brush 21a3 or brush 21b3) positioned at the second position and swung by the swing mechanism 42a is brought into contact with the upper surface of the self-cleaning substrate 53, whereby the brush is cleaned using the cleaning liquid supplied by the cleaning liquid supply unit 54. In other words, the brush is moved while being in contact with the upper surface of the self-cleaning substrate 53 to which the cleaning liquid is supplied, so that the brush is cleaned.

The brush (brush 31a3 or brush 31b3) positioned at the second position and swung by the swing mechanism 42b is brought into contact with the lower surface of the self-cleaning substrate 53, whereby the brush is cleaned using the cleaning liquid supplied by the cleaning liquid supply unit 55. In other words, the brush is moved while being in contact with the lower surface of the self-cleaning substrate 53 to which the cleaning liquid is supplied, so that the brush is cleaned. The self-cleaning substrate 53 is a plate-shaped body formed of silicon, quartz, or the like and having the same thickness as the substrate W.

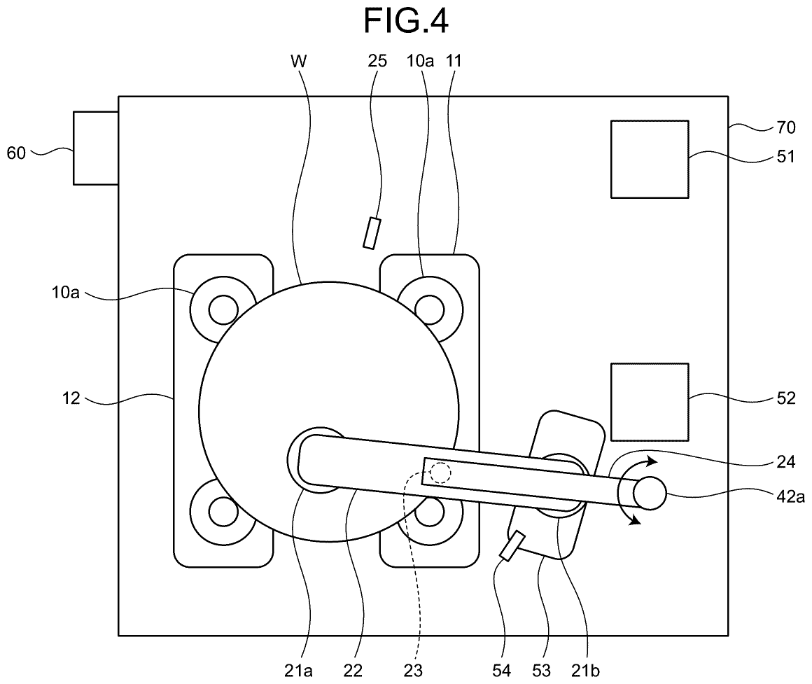

FIG. 4 is a diagram for explaining a case where the first cleaning head and the second cleaning head according to the embodiment swing. The example of FIG. 4 illustrates a case where the brush of the first cleaning head is positioned at the first position and the brush of the second cleaning head is positioned at the second position.

As illustrated in FIG. 4, the first swing arm 24 swings about the swing mechanism 42a, and the second swing arm 34 (see FIG. 2) similarly swings about the swing mechanism 42b, whereby the first cleaning head and the second cleaning head swing. In the example of FIG. 4, while the first cleaning head cleans both surfaces (the first surface and the second surface) of the substrate W, the brush of the second cleaning head is cleaned (self-cleaned) by the self-cleaning substrate 53 and the cleaning liquid supply units 54 and 55.

The control device 60 controls each unit of the substrate processing apparatus 1. In order to realize various functions of the substrate processing apparatus 1, the control device 60 has a processor for executing a program, a memory for storing various kinds of information such as programs and operation conditions, and a drive circuit for driving each component. The control device 60 controls the rotation mechanism 10, the first cleaning mechanism 20, the second cleaning mechanism 30, the drive mechanism 40, and the brush cleaning unit 50. The control device 60 is, for example, an example of a control unit or a controller.

The control device 60 controls each unit of the substrate processing apparatus 1, whereby the substrate processing apparatus 1 performs each of the processes of the substrate cleaning process, the brush cleaning process, and the rinse process. Note that, in the present embodiment, the substrate processing apparatus 1 performs a first brush cleaning process during the substrate cleaning process, and performs a second brush cleaning process after the substrate cleaning process.

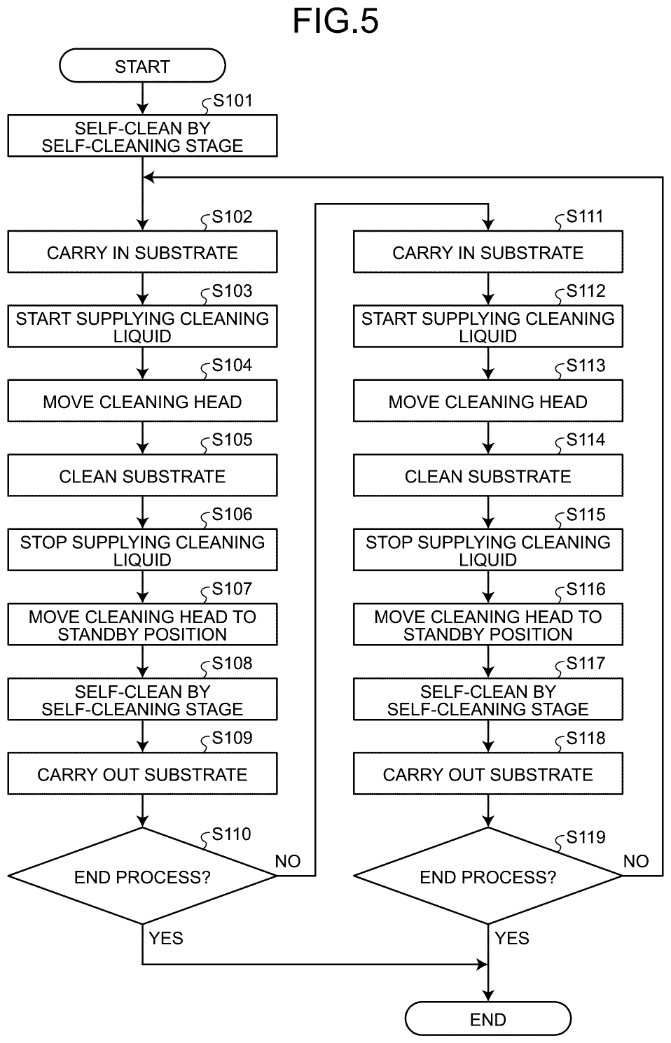

FIG. 5 is a flowchart illustrating a flow of an example of a process performed by the substrate processing apparatus 1 according to the embodiment. Note that a case where the performing of the process illustrated in FIG. 5 is started when the first cleaning head is positioned at the standby position P1 and the second cleaning head is positioned at the standby position P2 as illustrated in FIG. 1 will be described.

As illustrated in FIG. 5, first, the first self-cleaning stage 51 cleans the brush of the first cleaning head, and the second self-cleaning stage 52 cleans the brush of the second cleaning head (step S101).

When the substrate W is carried in, the rotation mechanism 10 rotates the carried-in substrate W in a held state (step S102).

Then, the cleaning liquid supply units 25 and 35 start supplying the cleaning liquid to both surfaces of the substrate W (step S103).

Then, the swing mechanisms 42a and 42b move the first cleaning head to the first cleaning start position and move the second cleaning head to the second cleaning start position (step S104). Here, the first cleaning start position is a position of the cleaning head when two brushes of the cleaning head (any one of the first cleaning head and the second cleaning head) come into contact with both surfaces of the substrate W to clean both surfaces of the substrate W, and is a position of the cleaning head when cleaning of the substrate W is started by the cleaning head. Further, the second cleaning start position is a position of the cleaning head when the two brushes of the cleaning head (the other one of the first cleaning head or the second cleaning head) come into contact with both surfaces of the self-cleaning substrate 53 to self-clean the two brushes, and is a position of the cleaning head when cleaning of the cleaning head is started by the self-cleaning substrate 53.

Then, the first cleaning head performs the substrate cleaning process of cleaning both surfaces of the substrate W by swinging the first cleaning head from the outer periphery of the substrate W to the outer periphery on the opposite side thereof through the center thereof while rotating the brush, and the self-cleaning substrate 53 performs the first brush cleaning process of cleaning the two brushes of the second cleaning head (step S105). In other words, the substrate processing apparatus 1 performs the first brush cleaning process during the substrate cleaning process.

When the performing of the substrate cleaning process is completed, the cleaning liquid supply units 25 and 35 stop supplying the cleaning liquid to both surfaces of the substrate W (step S106).

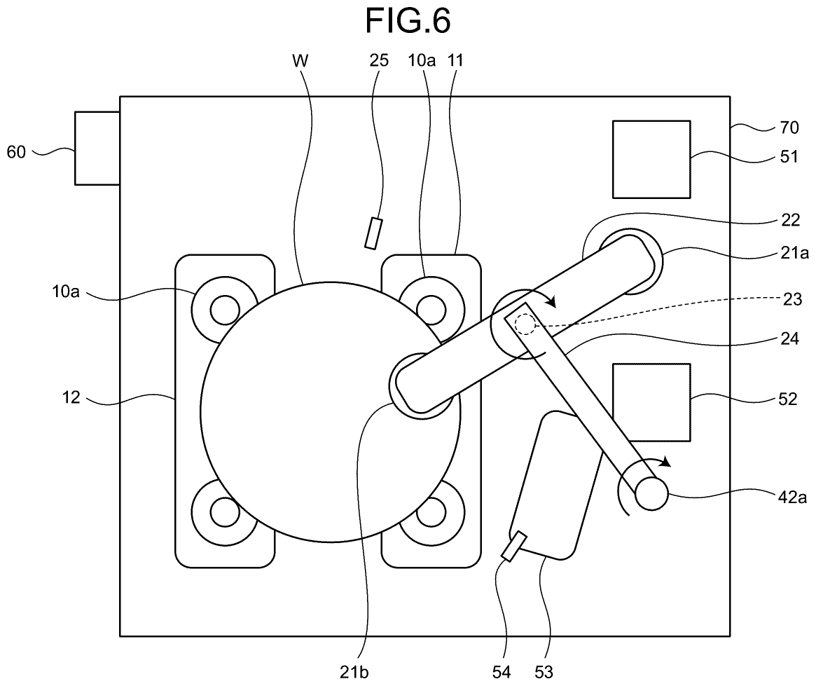

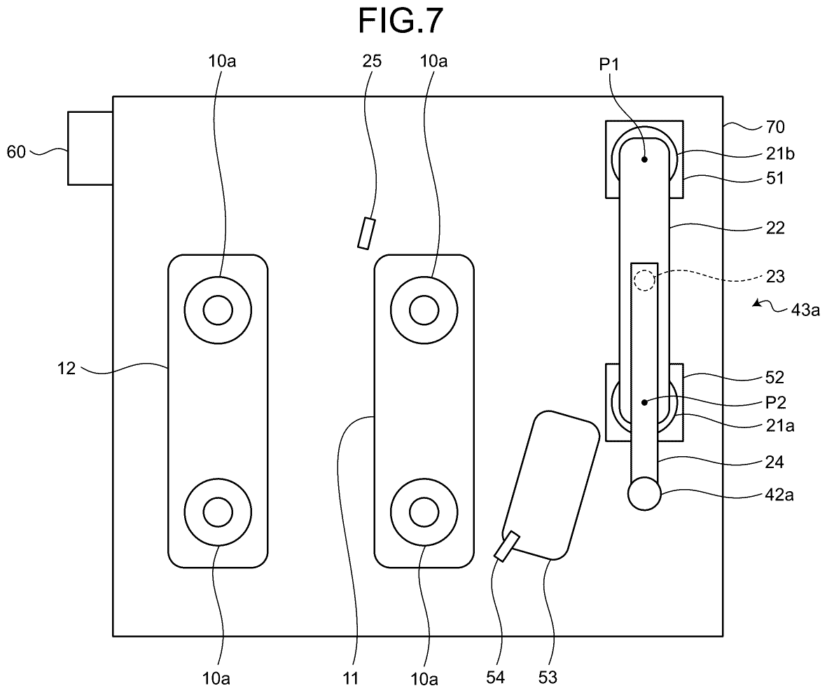

Then, the control device 60 controls each mechanism so that the second cleaning head is positioned at the standby position P1 and the first cleaning head is positioned at the standby position P2 (step S107). FIG. 6 is a diagram illustrating an example of the operation of the substrate processing apparatus 1 in step S107 according to the embodiment. FIG. 7 is a diagram illustrating an example of the state after the operation of the substrate processing apparatus 1 in step S107 according to the embodiment. First, the lift mechanism 41a lifts the first swing arm 24, and the lift mechanism 41b lowers the second swing arm 34. Thus, the two brushes of the first cleaning head are isolated from both surfaces of the substrate W. Further, the two brushes of the second cleaning head are isolated from both surfaces of the self-cleaning substrate 53. In such a state, the second cleaning head is moved to be positioned at the standby position P1, and the first cleaning head is moved to be positioned at the standby position P2. In other words, as illustrated in FIG. 6, while the swing mechanisms 42a and 42b swing the first swing arm 24 and the second swing arm 34, the turning mechanisms 43a and 43b turn the first turning arm 22 and the second turning arm 32. Thus, as illustrated in FIG. 7, the second cleaning head is positioned at the standby position P1, and the first cleaning head is positioned at the standby position P2.

Then, the second brush cleaning process is performed in which the first self-cleaning stage 51 cleans the brush of the second cleaning head and the second self-cleaning stage 52 cleans the brush of the first cleaning head (step S108). In other words, the substrate processing apparatus 1 performs the second brush cleaning process (step S108) after the substrate cleaning process (step S105).

Then, the rotation mechanism 10 stops the rotation of the substrate W and releases the substrate W (step S109). In step S109, the released substrate W is carried out.

Then, the control device 60 determines whether or not to end the process (step S110). For example, if there is a substrate W to be processed next (a substrate to be newly carried in), the control device 60 determines not to end the process. On the other hand, if there is no substrate W to be processed next, the control device 60 determines to end the process. If the control device 60 determines to end the process, the process illustrated in FIG. 5 is ended. On the other hand, if the control device 60 determines not to end the process, the process proceeds to step S111.

When the substrate W to be processed next is carried in, the rotation mechanism 10 rotates the carried-in substrate W in a held state (step S111).

Then, the cleaning liquid supply units 25 and 35 start supplying the cleaning liquid to both surfaces of the substrate W (step S112).

Then, the swing mechanisms 42a and 42b move the second cleaning head to the first cleaning start position and move the first cleaning head to the second cleaning start position (step S113).

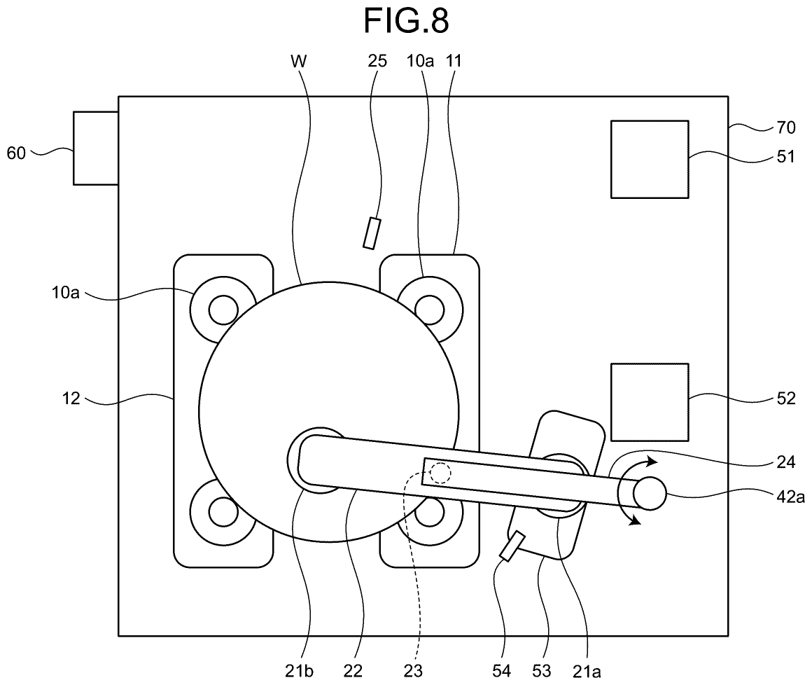

FIG. 8 is a diagram illustrating an example of the operation of the substrate processing apparatus 1 in step S114 according to the embodiment. Then, as illustrated in FIG. 8, the second cleaning head performs the substrate cleaning process of cleaning both surfaces of the substrate W by swinging from the outer periphery of the substrate W to the outer periphery on the opposite side thereof through the center thereof while rotating the brush, and the self-cleaning substrate 53 performs the first brush cleaning process of cleaning the two brushes of the cleaning head (first cleaning head) (step S114). In other words, the substrate processing apparatus 1 performs the first brush cleaning process during the substrate cleaning process. Further, the substrate processing apparatus 1 switches the cleaning head used for the substrate cleaning process for each substrate W. Further, the substrate processing apparatus 1 switches the cleaning head used for the first brush cleaning process for each substrate W.

When the performing of the substrate cleaning process is completed, the cleaning liquid supply units 25 and 35 stop supplying the cleaning liquid to both surfaces of the substrate W (step S115).

Then, while the swing mechanisms 42a and 42b swing the first swing arm 24 and the second swing arm 34 such that the first cleaning head is positioned at the standby position P1 and the second cleaning head is positioned at the standby position P2, the turning mechanisms 43a and 43b turn the first turning arm 22 and the second turning arm 32 (step S116). Thus, the first cleaning head is positioned at the standby position P1, and the second cleaning head is positioned at the standby position P2.

Then, the second brush cleaning process is performed in which the first self-cleaning stage 51 cleans the brush of the first cleaning head and the second self-cleaning stage 52 cleans the brush of the second cleaning head (step S117). In other words, the substrate processing apparatus 1 performs the second brush cleaning process (step S117) after the substrate cleaning process (step S114).

Then, the rotation mechanism 10 stops the rotation of the substrate W and releases the substrate W (step S118). In step S118, the released substrate W is carried out.

Then, the control device 60 determines whether or not to end the process in the same manner as the determination in step S110 (step S119). If the control device 60 determines to end the process, the process illustrated in FIG. 5 is ended.

On the other hand, if the control device 60 determines not to end the process, the process returns to step S102, and the substrate processing apparatus 1 performs each of the processes of step S102 and subsequent steps again on the substrate W to be processed next. Therefore, every time the substrates W are successively carried in, the rotation mechanism 10 rotates the carried-in substrates W in a held state. Then, the control device 60 switches the cleaning head for cleaning the surface of the substrate W every time a predetermined number of substrates (one substrate W in the present embodiment) are cleaned. The control device 60 switches the cleaning head for cleaning the surface of the substrate W by controlling the turning mechanisms 43a and 43b to turn the turning arms 22 and 32.

The substrate processing apparatus 1 according to the embodiment has been described above. The substrate processing apparatus 1 includes the rotation mechanism 10, the cleaning liquid supply units 25 and 35, the first cleaning head, the second cleaning head, the turning arms 22 and 32, and the control device 60. The rotation mechanism 10 rotates the substrate W in a held state. The cleaning liquid supply units 25 and 35 supply a cleaning liquid to the substrate W rotated by the rotation mechanism 10. The first cleaning head cleans both surfaces of the substrate W by bringing the brush into contact with both surfaces of the substrate rotated by the rotation mechanism 10. The second cleaning head cleans both surfaces of the substrate W by bringing the brush into contact with both surfaces of the substrate rotated by the rotation mechanism 10. The turning arms 22 and 32 have one end to which the first cleaning head is attached and the other end to which the second cleaning head is attached, and turn the first cleaning head and the second cleaning head. The control device 60 controls the rotation mechanism 10, the cleaning liquid supply units 25 and 35, and the turning arms 22 and 32. The control device 60 controls the turning arms 22 and 32 such that, during cleaning in which the brush of one cleaning head of the first cleaning head and the second cleaning head is brought into contact with the surface of the substrate W to perform cleaning, the brush of the other cleaning head of the first cleaning head and the second cleaning head is positioned at a position outside the substrate W.

With such a configuration, the substrate processing apparatus 1 can clean the surface of the substrate W by switching the brush of the first cleaning head and the brush of the second cleaning head. Therefore, it is possible to lengthen the time until each brush needs to be cleaned or replaced. In other words, it is possible to lengthen the time during which the substrate W can be cleaned by using the brush with less adhesion of contaminants and less accumulation of contaminants, thereby improving substrate quality.

Further, the control device 60 moves the first cleaning head and the second cleaning head to the standby positions P1 and P2 after cleaning of the substrate W by the brush of one cleaning head is completed. In other words, the control device 60 controls the swing mechanisms 42a and 42b to swing the first swing arm 24 and the second swing arm 34. The first self-cleaning stage 51 and the second self-cleaning stage 52 clean (self-clean) the brushes of both the first cleaning head and the second cleaning head positioned at the standby positions P1 and P2. The first self-cleaning stage 51 and the second self-cleaning stage 52 are, for example, an example of a cleaning unit.

According to such a configuration, the time for the brush to self-clean can be increased from the cleaning of the substrate W to the next cleaning of the substrate W. As an example, focusing on the brush 21a3 of the first cleaning head, during the period from the cleaning of the first substrate W by the brush 21a3 to the next cleaning of the substrate W by the brush 21a3, the self-cleaning can be performed in the time from the cleaning of the first substrate W to the start of the cleaning of the second substrate W and the time from the cleaning of the second substrate W by the brush 21b3 to the start of the cleaning of the third substrate W (cleaning by the brush 21a3).

Further, the self-cleaning substrate 53 cleans, during cleaning in which the brush of one cleaning head is brought into contact with the surface of the substrate W to perform cleaning, the brush of the other cleaning head positioned at a position outside the substrate W. The self-cleaning substrate 53 is, for example, an example of a cleaning unit.

According to such a configuration, even while the substrate W is being cleaned by the brush of one cleaning head, the brush of the other cleaning head can be cleaned (self-cleaned). By performing the self-cleaning of the brush, the substrate W can be cleaned using a clean brush.

Further, the cleaning liquid supply units 54 and 55 supply, during cleaning in which the brush of one cleaning head is brought into contact with the surface of the substrate W to perform cleaning, the cleaning liquid to the brush of the other cleaning head. In the present embodiment, the cleaning liquid supply units 54 and 55 supply the cleaning liquid to the self-cleaning substrate 53. The cleaning liquid supplied to the self-cleaning substrate 53 is supplied to the brush of the other cleaning head. In other words, the cleaning liquid supply units 54 and 55 supply the cleaning liquid to the brush of the other cleaning head via the self-cleaning substrate 53. According to this, the brush at the second position can be prevented from drying. When the brush is dried in a state in which the particles or the like are adhered to the brush, the particles may be fixed to the brush and may be difficult to be discharged to the outside of the brush. According to the present embodiment, since the brush can be maintained in a wet state, even if particles or the like adhere to the brush, the particles or the like can be satisfactorily discharged to the outside of the brush during the substrate cleaning or the self-cleaning.

The first cleaning head is provided at one end of each of the turning arms 22 and 32, and the second cleaning head is provided at the other end thereof. Further, the swing arms 24 and 34 turnably support the turning arms 22 and 32 and swing in a direction along the surface of the substrate W. The first cleaning head and the second cleaning head are moved by swinging the swing arms 24 and 34.

Thus, the brush of the first cleaning head and the brush of the second cleaning head can be moved (swung) along the same trajectory with respect to the substrate W and the nozzles (cleaning liquid supply units 25 and 35). If two arms each having one brush attached to the tip thereof are provided and the brushes attached to the respective arms are alternately used to clean the substrate W, there is a possibility that the trajectories of the brushes may change with respect to the rotation direction of the substrate W and the discharge direction of the cleaning liquid from the nozzle. On the other hand, according to the present embodiment, since two brushes can be moved along the same trajectory, a difference in cleaning performance between the two brushes can be suppressed. Therefore, the cleaning process can be uniformly performed between the plurality of substrates.

In addition, according to the present embodiment, since the number of swing mechanisms is smaller than the number of cleaning heads, the footprint of the substrate processing apparatus 1 can be reduced.

The self-cleaning substrate 53 cleans, during cleaning in which the brush of one cleaning head is brought into contact with the surface of the substrate W to perform cleaning, by coming into contact with the brush of the other cleaning head. After cleaning of the substrate W by the brush of one cleaning head is completed, the first self-cleaning stage 51 and the second self-cleaning stage 52 clean the brushes of both the first cleaning head and the second cleaning head moved to the standby position in a non-contact manner. Here, the first self-cleaning stage 51 and the second self-cleaning stage 52 are, for example, an example of a first cleaning unit, and clean the brushes of both the first cleaning head and the second cleaning head in a non-contact manner.

As described above, by performing both the non-contact cleaning and the contact cleaning, both the particles and the like adhered to the brush surface and the particles and the like entered the inside of the brush can be favorably discharged to the outside of the brush.

### Modifications

Various modifications of the above-described embodiment will now be described. For example, the cleaning (self-cleaning) of the brush at the standby positions P1 and P2 is not limited to the cleaning by the first self-cleaning stage 51 and the second self-cleaning stage 52 as described above. Further, in the first self-cleaning stage 51, the brush may be brought into contact with the upper surface and the lower surface of the cleaning member 51b, and in the second self-cleaning stage 52, the brush may be brought into contact with the upper surface and the lower surface of the cleaning member 51b.

In the self-cleaning substrate 53, the first self-cleaning stage 51, and the second self-cleaning stage 52, the cleaning liquid supplied to the brush is not limited to pure water. For example, SC-1 or an acid-based chemical liquid (hydrofluoric acid, nitric acid, hydrochloric acid, or the like) may be used. In addition, a plurality of kinds of cleaning liquids may be switched and supplied.

In the cleaning member 51b of the first self-cleaning stage 51 and the second self-cleaning stage 52, the through-hole 51bi into which the cleaning liquid flows is opened at the center of the upper surface of the cleaning member 51b and the center of the lower surface of the cleaning member 51b, but the present embodiment is not limited thereto. A plurality of openings communicating with the through-hole 51bi may be formed on the upper surface of the cleaning member 51b. By providing a plurality of openings instead of only one opening at the center of the upper surface of the cleaning member 51b, the cleaning liquid can be efficiently supplied to the entire brush. Similarly, a plurality of openings may be formed on the lower surface of the cleaning member 51b.

When the substrate W is cleaned, the brush may be moved on the substrate W by turning (moving) the cleaning heads about the turning shafts of the turning arms 22 and 32. In other words, when the surface of the substrate W is cleaned, the control device 60 controls the turning mechanisms 43a and 43b to turn the turning arms 22 and 32 such that the cleaning head is turned while bringing the brush of the cleaning head into contact with the surface of the substrate W. In this case, the self-cleaning substrate 53 may be provided only on a part of the trajectory of the brush at the second position, or may be provided so as to correspond to the entire trajectory. When the self-cleaning substrate 53 is provided so as to correspond to the entire trajectory of the brush at the second position, the self-cleaning substrate may be formed in an arc shape along the outer periphery of the substrate W.

Further, the swing arms 24 and 34 may be swung by the swing mechanisms 42a and 42b, and the turning arms 22 and 32 may be turned by the turning mechanisms 43a and 43b, thereby moving the brush to clean the surface of the substrate W.

In order to prevent the cleaning liquid from scattering from the self-cleaning substrate 53 and the brush to be self-cleaned on the self-cleaning substrate 53 and adhering to the substrate W, a partition wall that covers the periphery of the self-cleaning substrate 53 may be provided.

Further, the self-cleaning substrate 53 may not be provided.

The first cleaning head (the brush 21a3 and the brush 31a3) and the second cleaning head (the brush 21b3 and the brush 31b3) may be individually capable to move up and down with respect to the turning arms 22 and 32. In this case, instead of the self-cleaning substrate 53 and the cleaning liquid supply units 54 and 55 for supplying the cleaning liquid to the self-cleaning substrate 53, a self-cleaning stage having the same configuration as the first self-cleaning stage 51 and the second self-cleaning stage 52 may be provided so that the self-cleaning can be performed in non-contact manner even at the second position.

Although the example in which the two self-cleaning stages of the first self-cleaning stage 51 and the second self-cleaning stage 52 are provided has been described, one self-cleaning stage may be provided, and, at the standby position, the brush of one cleaning head may be positioned at the self-cleaning stage and the brush of the other cleaning head may be positioned at a position in contact with the self-cleaning substrate 53. In other words, the self-cleaning stage is provided at a position spaced apart from the self-cleaning substrate 53 by a distance corresponding to the distance between the two brushes 21a3 and 21b3 provided on the second turning arm 32 in plan view. An example of a specific operation of the substrate processing apparatus 1 in this case will be described. The control device 60 controls the swing mechanisms 42a and 42b and the turning mechanisms 43a and 43b such that, after cleaning of the substrate W by the brush of one cleaning head is completed, any one of the first cleaning head and the second cleaning head is moved to the standby position (self-cleaning stage). The control device 60 controls the self-cleaning stage such that the brush of the one cleaning head positioned at the standby position is cleaned. The control device 60 controls, during cleaning of the brush of the cleaning head positioned at the standby position by the self-cleaning stage, the brush of the other cleaning head to be cleaned by the self-cleaning substrate 53. The self-cleaning stage is, for example, an example of a first cleaning unit. The self-cleaning substrate 53 and the cleaning liquid supply units 54 and 55 are, for example, an example of a second cleaning unit.

When the cleaning head is positioned at the standby position P1 or the standby position P2 (when the cleaning head is positioned at a position where the cleaning head can be cleaned by the first self-cleaning stage 51 or the second self-cleaning stage 52), the cleaning liquid may be continuously supplied from the cleaning liquid supply units 54 and 55 to the self-cleaning substrate 53, or the supply of the cleaning liquid from the cleaning liquid supply units 54 and 55 may be stopped. In addition, after the brush is retracted from the standby position P1 or the standby position P2, the cleaning liquid may be continuously supplied from the cleaning liquid supply units 54 and 55 to the self-cleaning substrate 53 for a predetermined time, and then the supply may be stopped.

When the first cleaning head and the second cleaning head are positioned at the standby positions P1 and P2, the cleaning liquid is supplied to the self-cleaning substrate 53, whereby the self-cleaning substrate 53 can be washed and cleaned. Thus, when the next substrate W is carried in and the brush is self-cleaned, the brush can be prevented from being contaminated by particles or the like adhered to the self-cleaning substrate 53. An example of a specific operation of the substrate processing apparatus 1 in this case will be described. The cleaning unit includes a self-cleaning substrate 53 and cleaning liquid supply units 54 and 55 for supplying a cleaning liquid to the self-cleaning substrate 53, and cleans the brush of the other cleaning head by using the cleaning liquid supplied to the self-cleaning substrate 53. The control device 60 controls the cleaning liquid supply units 54 and 55 such that the cleaning liquid is supplied to the self-cleaning substrate 53 even after cleaning of the brush of the other cleaning head is completed.

The example in which the substrate processing apparatus 1 has the brush for cleaning the first surface of the substrate W and the brush for cleaning the second surface of the substrate W and cleans both surfaces of the substrate W has been described. However, the substrate processing apparatus 1 may include a brush for cleaning any one of the first surface and the second surface of the substrate W. In other words, in the substrate processing apparatus 1, the brush may clean at least one surface of the substrate W. Therefore, the substrate processing apparatus 1 may at least include any one of the first cleaning mechanism 20 or the second cleaning mechanism 30.

Although an example in which the substrate processing apparatus 1 switches the brush for cleaning the substrate W every time one substrate W is processed has been described, the brush may be switched every time a plurality of substrates W is processed.

According to an aspect of the embodiments, it is possible to provide a substrate cleaning apparatus and a substrate cleaning method capable of improving substrate quality.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate cleaning apparatus comprising:
a rotation mechanism configured to rotate a substrate in a held state;
a cleaning liquid supply unit configured to supply a cleaning liquid to the substrate rotated by the rotation mechanism;
a first cleaning head having a first brush and configured to clean at least one surface of the substrate rotated by the rotation mechanism by bringing the first brush into contact with the one surface of the substrate;
a second cleaning head having a second brush and configured to clean the one surface of the substrate by bringing the second brush into contact with the one surface of the substrate;
a turning arm having one end to which the first cleaning head is attached and another end to which the second cleaning head is attached, the turning arm configured to turn the first cleaning head and the second cleaning head; and
a controller configured to control the rotation mechanism, the cleaning liquid supply unit, and the turning arm, wherein
the controller controls the turning arm such that, during cleaning in which a brush of one cleaning head of the first cleaning head and the second cleaning head is brought into contact with a surface of the substrate to perform cleaning, a brush of another cleaning head of the first cleaning head and the second cleaning head is positioned at a position outside the substrate.

2. The substrate cleaning apparatus according to claim 1,
wherein the controller turns the turning arm such that a cleaning head for cleaning the surface of the substrate is switched every time a predetermined number of the substrates are cleaned.

3. The substrate cleaning apparatus according to claim 1,
wherein the controller moves the first cleaning head and the second cleaning head to a standby position after cleaning of the substrate by the brush of the one cleaning head is completed, the substrate cleaning apparatus comprising a cleaning unit configured to clean brushes of both the first cleaning head and the second cleaning head positioned at the standby position.

4. The substrate cleaning apparatus according to claim 1, comprising a cleaning unit configured to clean, during cleaning in which the brush of the one cleaning head is brought into contact with the surface of the substrate to perform cleaning, the brush of the other cleaning head positioned at the position outside the substrate.

5. The substrate cleaning apparatus according to claim 1, comprising a supply unit configured to supply, during cleaning in which the brush of the one cleaning head is brought into contact with the surface of the substrate to perform cleaning, a cleaning liquid to the brush of the other cleaning head.

6. The substrate cleaning apparatus according to claim 1, comprising:
a first cleaning unit configured to clean, after cleaning of the substrate by the brush of the one cleaning head is completed, the brushes of both the first cleaning head and the second cleaning head moved to a standby position in a non-contact manner; and
a second cleaning unit configured to clean, during cleaning in which the brush of the one cleaning head is brought into contact with the surface of the substrate to perform cleaning, the brush of the other cleaning head by coming into contact with the brush of the other cleaning head.

7. The substrate cleaning apparatus according to claim 1, comprising a swing arm which turnably supports the turning arm and swings in a direction along the one surface of the substrate, wherein
the first cleaning head and the second cleaning head are moved by swinging the swing arm.

8. The substrate cleaning apparatus according to claim 1, comprising:
a first cleaning unit configured to clean a brush of one of the first cleaning head and the second cleaning head which is positioned at a standby position; and
a second cleaning unit configured to clean, during cleaning in which the brush of the one cleaning head is brought into contact with the surface of the substrate to perform cleaning, the brush of the other cleaning head, wherein
the controller controls one of the first cleaning head and the second cleaning head such that, after cleaning of the substrate by the brush of the one cleaning head is completed, the one of the first cleaning head and the second cleaning head is moved to the standby position and controls the first cleaning unit such that the brush of a cleaning head positioned at the standby position is cleaned, and
the controller controls the second cleaning unit such that, during cleaning of the brush of the cleaning head positioned at the standby position by the first cleaning unit, a brush of a cleaning head of which the cleaning of the brush is not performed by the first cleaning unit, of the first cleaning head and the second cleaning head, is cleaned.

9. The substrate cleaning apparatus according to claim 4, wherein
the cleaning unit comprises a self-cleaning substrate and a supply unit configured to supply a cleaning liquid to the self-cleaning substrate, and cleans the brush of the other cleaning head by using the cleaning liquid supplied to the self-cleaning substrate, and
the controller controls the supply unit such that the cleaning liquid is supplied to the self-cleaning substrate even after cleaning of the brush of the other cleaning head is completed.

10. A substrate cleaning method performed by a substrate cleaning apparatus, the substrate cleaning apparatus comprising: a first cleaning head having a first brush and configured to clean at least one surface of a rotating substrate by bringing the first brush into contact with the one surface of the substrate; a second cleaning head having a second brush and configured to clean the one surface of the substrate by bringing the second brush into contact with the one surface of the substrate; and a turning arm having one end to which the first cleaning head is attached and another end to which the second cleaning head is attached, the turning arm configured to turn the first cleaning head and the second cleaning head, the substrate cleaning method comprising the steps of:
rotating a substrate while holding the substrate;
supplying a cleaning liquid to the rotated substrate; and
controlling the turning arm such that, during cleaning in which a brush of one cleaning head of the first cleaning head and the second cleaning head is brought into contact with a surface of the substrate to perform cleaning, a brush of another cleaning head of the first cleaning head and the second cleaning head is positioned at a position outside the substrate.
